(19) United States
(12) Patent Application Publication
(10) Pub. No.: US 2019/0043776 A1
(43) Pub. Date: Feb. 7, 2019

(54) DUAL-SIDED PACKAGE ASSEMBLY PROCESSING

(71) Applicant: Intel Corporation, Santa Clara, CA (US)

(72) Inventors: Pramod MALATKAR, Chandler, AZ (US); Aleksandar ALEKSOV, Chandler, AZ (US); Dilan SENEVIRATNE, Phoenix, AZ (US); Edvin CETEGEN, Chandler, AZ (US)

(73) Assignee: Intel Corporation, Santa Clara, CA (US)

(21) Appl. No.: 16/074,755

(22) PCT Filed: Apr. 2, 2016
(86) PCT No.: PCT/US2016/025778

§ 371 Date: Aug. 1, 2018

(51) Int. Cl. H01L 23/31; H01L 21/56; H01L 25/065

(52) U.S. Cl. CPC H01L 23/3121; H01L 25/0655; H01L 21/566

(57) ABSTRACT

Techniques and mechanisms for providing packaged circuitry. In an embodiment, first circuit structures are coupled to a release layer on a first side of a substrate, and second circuit structures are coupled to another release layer on a second side of the substrate. Respective portions of mold compound are variously injection molded or otherwise deposited around the first circuit structures and around the second circuit structures. The mold compound portions are cured while the first circuit structures and the second circuit structures are on opposite respective sides of the substrate. In another embodiment, the first circuit structures and the second circuit structures are separated from each other and from the substrate, after curing of the mold compound portions, to form distinct packaged devices.

### BACKGROUND

### 1. Technical Field

Embodiments described herein generally relate to packaged circuit devices and more particularly, but not exclusively, to processing for disposing a packaging material on circuit structures.

### 2. Background Art

Integrated circuits are typically assembled into a package that is subsequently to be mounted to a printed circuit board or other such structure. Packaged circuit devices include active circuit components, passive circuit components, conductive traces or other circuit structures that are enclosed by a protective mold material. The mold material is typically formed with an injection mold process.

Injection mold processes are susceptible to causing a package to warp. Such warpage can complicate the attachment of a packaged device to external structures. Moreover, warpage of a packaged device can contribute to stresses on internal circuit components, as well as problems with the operational characteristics of such internal circuit components.

### BRIEF DESCRIPTION OF THE DRAWINGS

The various embodiments of the present invention are illustrated by way of example, and not by way of limitation, in the figures of the accompanying drawings and in which:

FIG. 1 is an exploded view of a system to provide packaged circuitry according to an embodiment.

FIG. 2 is a flow diagram illustrating elements of a method to package circuit structures according to an embodiment.

FIGS. 3A, 3B, 3C are cross-sectional views of structures formed by assembly processing according to an embodiment.

FIGS. 4A, 4B show cross-sectional views of a system to provide packaged circuitry according to an embodiment.

FIG. 5 is a functional block diagram illustrating elements of a computer device according to an embodiment.

FIG. 6 is a functional block diagram illustrating elements of a computer system according to an embodiment.

### DETAILED DESCRIPTION

Embodiments described herein variously relate to techniques and mechanisms for packaging circuit structures on both sides of a substrate. Subsequently, such packaged structures may be separated from the substrate, and each other, to provide distinct packaged circuit devices. In packaging circuit structures on opposite respective sides of a substrate—e.g., including concurrently depositing and/or curing respective portions of mold compound (or “mold compound portions”) on such sides—some embodiments mitigate warpage that might otherwise result from package processing according to conventional, one-sided assembly techniques.

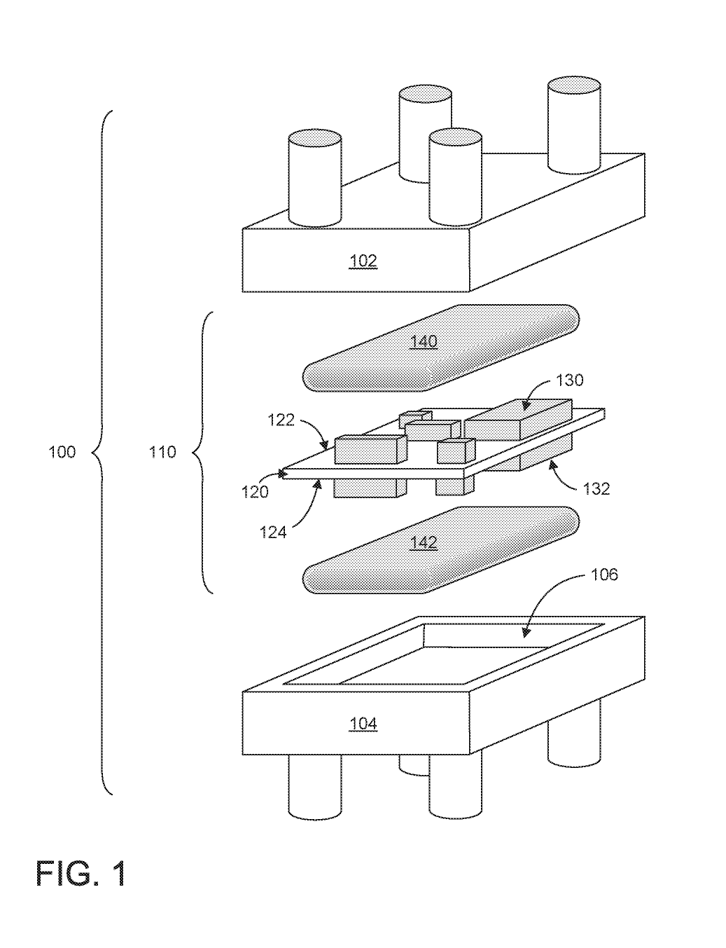

FIG. 1 shows an exploded view of a system 100 to form packaged circuit structures according to an embodiment. System 100 is one example of an embodiment wherein one or more packaging materials are variously deposited, directly or indirectly, on opposite sides of a substrate. The two sides of the substrate may each have respective circuit structures variously disposed directly or indirectly thereon—e.g., wherein packaging material is to be variously deposited on and/or around such circuit structures.

In the illustrative embodiment shown, system 100 includes a device 110 and mold halves 102, 104 to facilitate packaging of structures in device 110. After packaging by processes using mold halves 102, 104, device 110 may be further processed to form two or more separate packaged devices. For example, device 110 may include a substrate 120 and circuit structures 130, 132 variously disposed, directly or indirectly, on opposite sides 122, 124 of substrate 120.

Substrate 120 may include any of a variety of one or more at least semi-rigid structures—referred to herein as “one or more core layers” (e.g., including plastic, epoxy resin and/or other such materials)—to support positioning of circuit structures 130, 132. Coupling, fabrication and/or other deposition of circuit structures 130 on side 122—and/or deposition of circuit structures 132 on side 124—may include any of a variety of additive and/or subtractive processes. Such processes may include, but are not limited to, one or more mask, etch, lithography, metallization (e.g., electroplating), attachment (e.g., wire bonding, soldering, etc.) and/or other operations adapted, for example, from conventional circuit manufacturing techniques. One or both of circuit structures 130, 132 may each include any of a variety of combinations of passive circuit components, active circuit components and/or conductive interconnect structures (e.g., including signal traces). For example, circuit structures 130, 132 may be variously configured each to provide a respective processor, controller, data storage, communication and/or other capability. Some embodiments are not limited to a particular functionality that might be provided by circuit structures 130, 132.

Substrate 120 may further include, or couple to, one or more structures that facilitate a subsequent separation of circuit structures 130 from some or all of substrate 120. Alternatively or in addition, such one or more structures may facilitate separation of circuit structures 132 from some or all of substrate 120. For example, substrate 120 may further include or couple to peelable or otherwise separable release films (not shown) each forming, or disposed on, a different respective one of sides 122, 124.

Packaging of device 110 may include positioning substrate 120 (and the circuit structures 130, 132 variously coupled thereto) between mold halves 102, 104. Prior to or after such positioning, a mold compound 142 may be disposed under side 124 and circuit structures 132—e.g., wherein a mold compound 140 may be disposed over side 122 and circuit structures 130. Mold compounds 140, 142 may include any of a variety of epoxy resins and/or other material adapted, for example, from conventional techniques for the manufacture of rigid packaged devices. Alternatively, mold compounds 140, 142 may include an elastomer (e.g., thermoplastic polyurethane) and/or any of various other package materials used in conventional techniques for manufacturing flexible packaged circuit devices. Compounds 140, 142 may comprise the same compound material, although some embodiments are not limited in this regard. Deposition of compounds 140, 142 may include injection molding, although some embodiments are not limited in this regard.

One or more pistons, shafts, alignment tracks and/or other structures may facilitate bringing mold halves 102, 104 into position on opposite sides of substrate 120. Together, mold halves 102, 104 may form a mold that is to facilitate deposition, shaping, etc. of compounds 140, 142. For example, a recess 106 formed by mold half 104 may accommodate compound 142 and/or some or all of circuit structures 132. Similarly, mold half 102 may form another recess (not shown)—e.g., to be aligned with recess 106—for accommodating compound 140 and/or some or all of circuit structures 130. While disposed between mold halves 102, 104, compounds 140, 142 may be cured—e.g., by application of heat, pressure and/or other the like—to form a package structure around circuit structures 130 and another package structure around circuit structures 132.

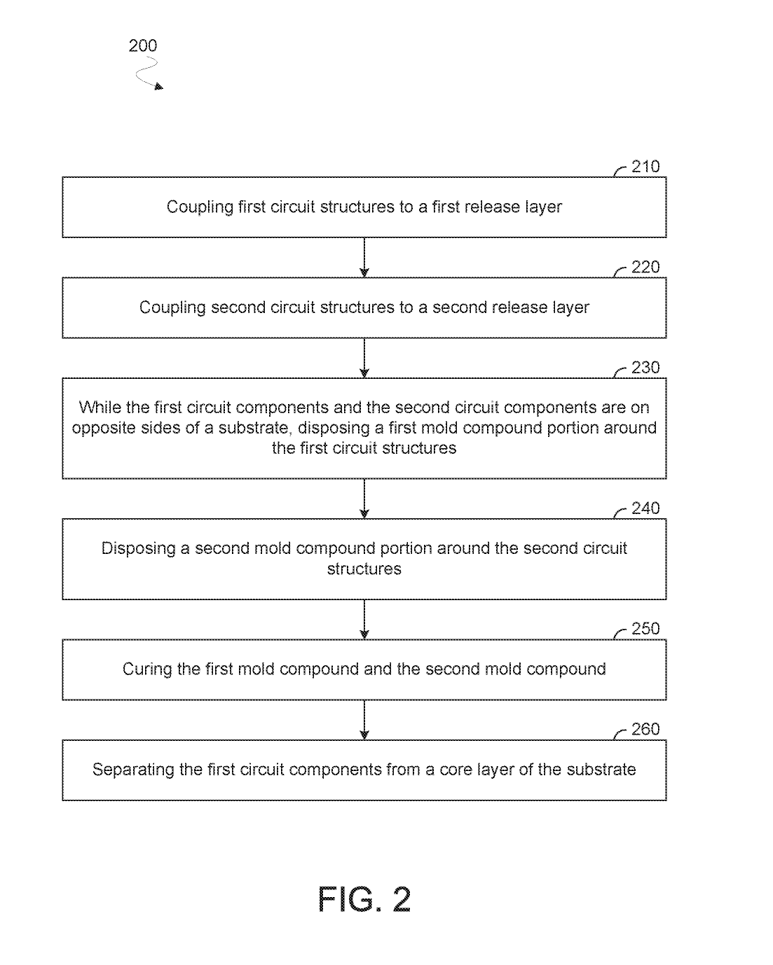

FIG. 2 illustrates elements a method 200 to provide packaged circuitry according to an embodiment. Method 200 is one example of processing to form packaging structures that are coupled, directly or indirectly, each to a different respective side of a substrate. For example, method 200 may provide a device having some of all of the features of device 110, e.g., wherein operations of method 200 are performed using mold halves 102, 104.

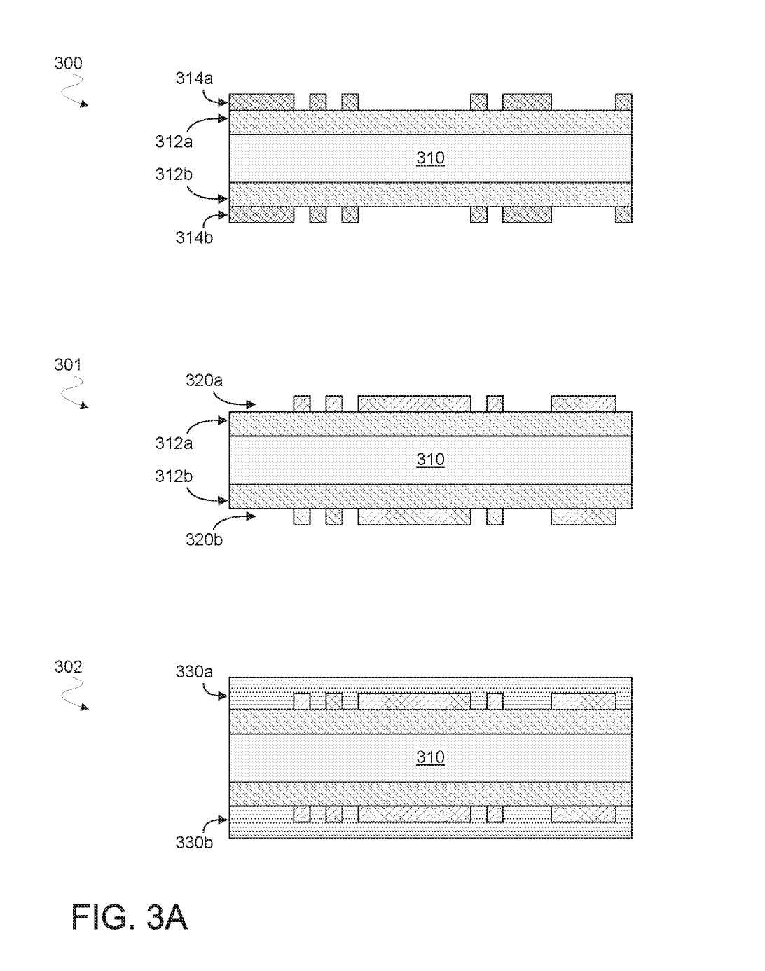

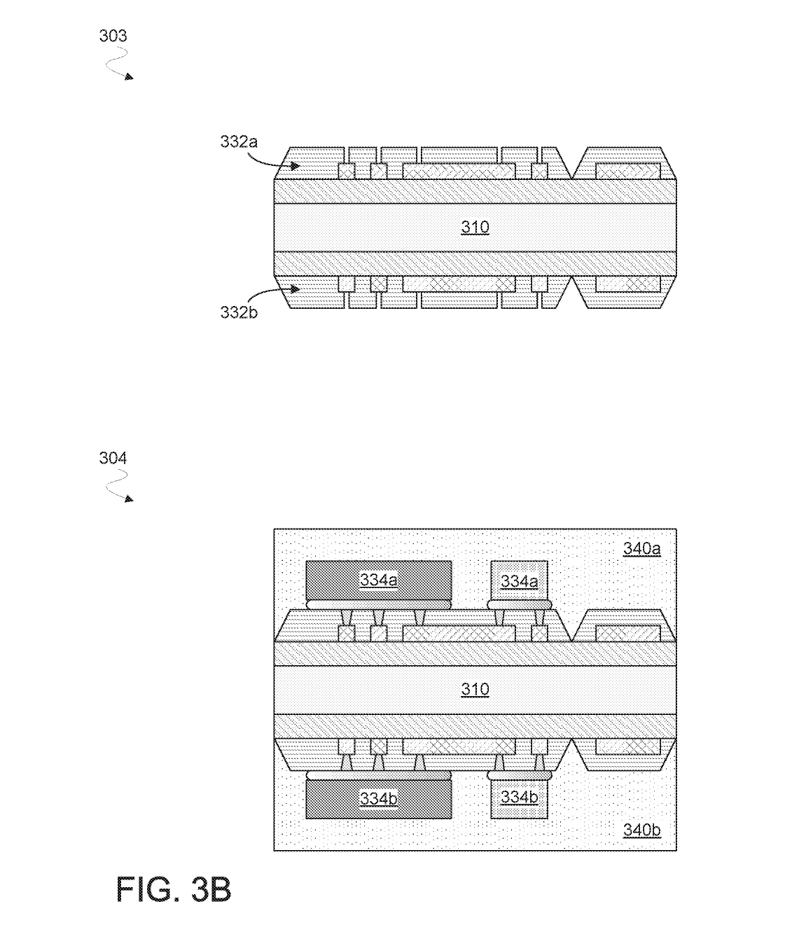

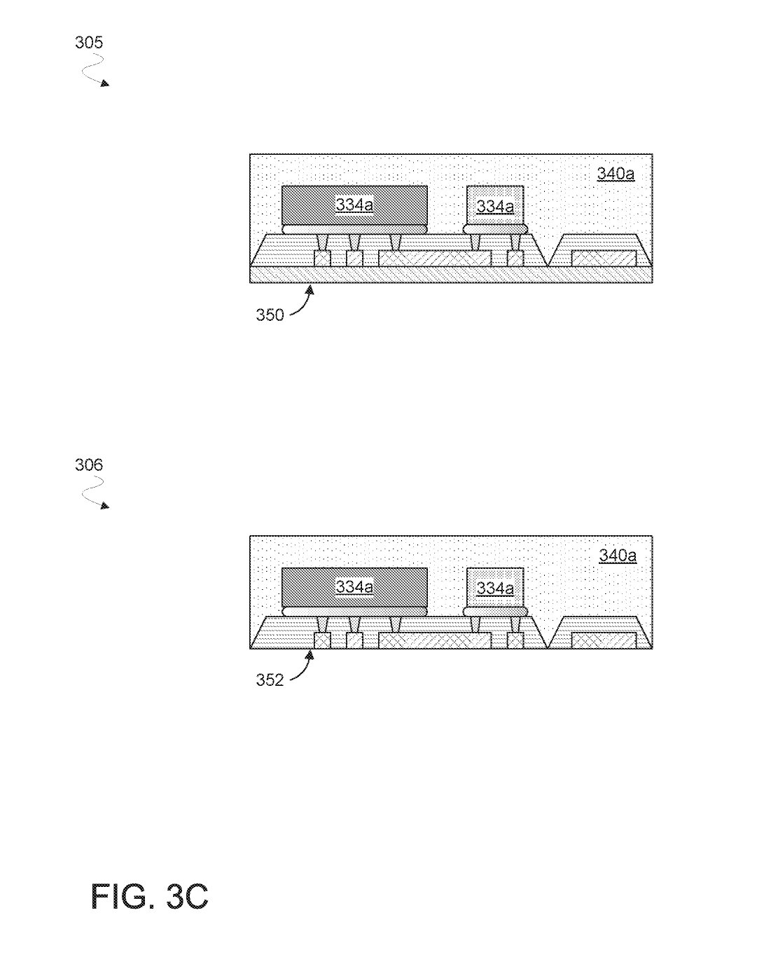

To illustrate certain features of various embodiments, method 200 is described herein with reference to structures formed by processing stages 301-306—as shown in FIGS. 3A-3C—for the formation of one or more packaged circuit devices. However, such discussion may be extended to apply to any of a variety of additional or alternative structures, according to different embodiments. Moreover, the processing represented by stages 301-306 may include additional and/or alternative operations to those of method 200, in some embodiments.

Method 200 may include, at 210, coupling first circuit structures to a first release layer and, at 220, coupling second circuit structures to a second release layer. The first release layer and the second release layer may include one or more peelable films and/or other such structures to facilitate the separation of packaged circuitry from opposite sides of a substrate which includes one or more core layers. The coupling at 210 may include first processing to fabricate and/or otherwise couple the first circuit structures directly or indirectly on a first side of the substrate—the first side formed by or adjoining the first release layer—while the second release layer forms or adjoins a second side of the substrate. Second processing—subsequent to such first processing—may include one or more of operations at 220 to fabricate or otherwise couple the second circuit structures on the second side.

In another embodiment, the coupling at 210 and at 220 includes variously fabricating and/or otherwise coupling the first circuit structures and the second circuit structures on different respective core layer portions—each indirectly via a respective one of the first release layer and the second release layer. Subsequently, such core layer portions may be subsequently coupled to one another to form the substrate at least in part. By way of illustration and not limitation, the core layer portions may be different respective portions of a handling layer (or other such structure) that are separated from one another and subsequently adhered or otherwise coupled in a stacked arrangement to form the substrate.

Referring now to stage 300, release layers 312a, 312b may be formed on opposite respective sides of a substrate 310 comprising one or more core layers. Substrate 310 may comprise plastic, epoxy, glass, metal and/or any of a variety of other handling layer materials adapted, for example, from conventional structures for fabricating, assembling and/or otherwise positioning circuit structures for packaging. Release layers 312a, 312b may comprise a peelable film (e.g., having a prepreg structure) and/or any of a variety of other structures that facilitate a subsequent separation of circuit structures and/or packaging material from substrate 310. Release layers 312a, 312b may include one or more plastic, silicone and/or other suitable materials—e.g., used in conventional release structures—configured to be peeled, delaminated or otherwise separated from one or more core layers of substrate 310. For example, release layers 312a, 312b include a synthetic polymer such as polytetrafluoroethylene, polyimide or the like. In an embodiment, release layers 312a, 312b include or are otherwise treated with a releasing agent that can be chemically, thermally or otherwise activated to induce separation from an adjoining structure.

At stage 300, patterned masks 314a, 314b (e.g., comprising any of a variety of conventional dry mask film materials) may be variously formed on release layers 312a, 312b, respectively. As shown at stage 301, patterned masks 314a, 314b may be variously etched or otherwise removed after metallization processes (e.g., including electroplating) to form patterned metal layers 320a, 320b on respective release layers 312a, 312b. Patterned metal layers 320a, 320b may include structures that are to function as respective conductive contacts of one or more hardware interface or, alternatively, are to facilitate coupling of such conductive contacts at an exterior of a final packaged device resulting from the processing of stages 300-306.

Referring now to stage 302, layers 330a, 330b of one or more insulator materials (e.g., including any of various solder resist materials, photoimageable dielectrics and/or the like) may be deposited over the respective patterned metal layers 320a, 320b. Additional pattern processing—e.g., including mask, exposure, development, cure and/or other operations adapted, for example, from conventional lithographic techniques—may be performed to generate patterned insulator layers 332a, 332b from layers 330a, 330b. In some embodiments, substrate 310 is formed by cutting of a larger substrate into strips (not shown)—e.g., where such cutting is performed after formation of patterned insulator layers 332a, 332b. Patterned insulator layers 332a, 332b may expose portions of patterned metal layers 320a, 320b for subsequent coupling to other respective circuit structures. By way of illustration and not limitation, circuit components 334a may be variously soldered, bonded or otherwise coupled, at stage 303, to respective contacts of patterned metal layer 320a. Alternatively or in addition, circuit components 334b may be variously coupled to respective contacts of patterned metal layer 320b. Although certain embodiments are not limited in this regard, some or all of circuit components 334a, 334b may be variously coupled each to a respective patterned insulator layer via an underfill material that, for example, provides an interface to accommodate differences between the respective coefficients of thermal expansion for adjoining materials. Any of a variety of organic polymers, inorganic fillers and/or other conventional underfill materials may be adapted for use in some embodiments.

Circuit components 334a, 334b may include any of a variety of passive circuit elements and/or active circuit elements. By way of illustration and not limitation, circuit components 334a, 334b may include one or more distinct capacitors and/or inductors. Alternatively or in addition, circuit components 334a, 334b may include one or more IC chips including processor logic, memory resources, controller circuitry and/or any of a variety of other types of integrated circuitry. Such one or more IC chips may include a system-on-chip (SoC), for example. In some embodiments, circuit components 334a, 334b include one or more packaged devices that are to be included in a package-in-package device generated by the processing of stages 300-306.

Method 200 may further comprise disposing a first mold compound portion around the first circuit structures, at 230, and disposing a second mold compound portion around the second circuit structures, at 240. The disposing at 230 (and the disposing at 240, for example) may be performed while the first circuit structures are coupled to the first release layer, while the second circuit structures are coupled to the second release layer, and while the first release layer and the second release layer are on opposite respective sides of a substrate including one or more core layers. For example, at stage 304, mold structure 340a may be deposited around (and, in an embodiment, over) circuit components 334a and/or some or all of patterned metal layer 320a. Similarly, mold structure 340b may be deposited around circuit components 334b and/or some or all of patterned metal layer 320b.

In an embodiment, the disposing at 230 and 240 includes injection (and/or other) molding that is performed concurrently on opposite sides of the substrate. The first mold compound portion and the second mold compound may include the same one or more mold compound materials. Alternatively, the first mold compound portion and the second mold compound portion may differ from one another with respect to at least one mold compound material.

Although some embodiments are not limited in this regard, method 200 may further comprise, at 250, curing the first mold compound portion and curing the second mold compound portion. Curing of the first mold compound may form a first package structure that, in at least a cross-sectional plane, surrounds some or all of the first circuit components (individually and/or collectively). Curing of the second mold compound may similarly form a second package structure that surrounds some or all of the second circuit components.

After the curing at 250, method 200 may, at 260, separate the first circuit components from at least one core layer of the substrate—e.g., by separating the first release layer from one of substrate and the first circuit structures and/or by separating the second release layer from one of substrate and the second circuit structures. The separating at 260 may form a first packaged device by separating the first package structure and the first circuit components from some or all of the substrate. In some embodiments, method 200 further comprises forming a second packaged device by separating the second package structure and the second circuit components from some or all of the substrate. After separation from the substrate, the first packaged structure (and/or the second packaged structure) may be flexible or, alternatively, at least partially rigid.

Referring now to FIG. 3C, separation of substrate 310 may form, at stage 305, a packaged device which includes circuit components 334a, patterned metal layer 320a, insulator layer 332a and the cured mold structure 340a. Although some embodiments are not limited in this regard, a side 350 of release layer 312a may be exposed by the separation of substrate 310 from the packaged circuit device. Release layer 312a may also be removed, at stage 306, to expose a side 352 of the packaged device. In some embodiments, another packaged device (not shown)—including circuit components 334b, patterned metal layer 320b, insulator layer 332b and mold structure 340b—may be similarly separated from the opposite side of substrate 310.

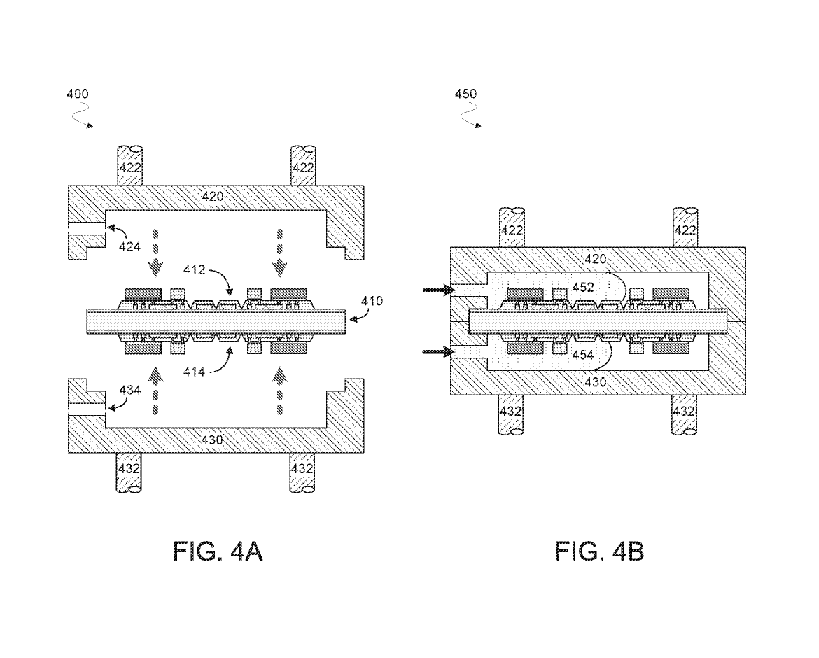

FIGS. 4A, 4B illustrates respective stages 400, 450 of processing, according to an embodiment, to dispose a package material on circuit structures that are variously formed on opposite sides of a substrate. Processing such as that represented by stages 400, 450 may include some or all of the features of method 200. For example, such processing may fabricate device 110 and/or a device such as that represented in one of stages 304-306.

As illustrated by stage 400, a side 412 of an assembly 410 may be brought into alignment with a mold half 420—e.g., wherein a side 414 of assembly 410 is brought into alignment with another mold half 430. Assembly 410 may include a substrate, comprising one or more core layers, as well as release layers disposed on opposite sides of the substrate. Assembly 410 may further include circuit structures—such as some or all of those variously shown in stages 303, 304—that are variously coupled to the substrate by respective ones of the release layers.

Mold half 420 may have formed therein a through hole 424 to accommodate an injection of a mold compound into a recess formed by mold half 420. Mold half 430 may similarly have another through hole 434 formed therein. Shafts 422, 432 may facilitate positioning of mold halves 420, 430 each at a respective one of sides 412, 414. As illustrated by stage 450, a mold compound 452 may be injected into through hole 424 and into a cavity formed between mold half 420 and side 412. Similarly, a mold compound 454 may be injected into through hole 434 and into another cavity formed between mold half 430 and side 414. In another embodiment, mold compounds 452, 454 may comprise respective platens that are variously placed each against a respective one of sides 412, 414 prior to an application of pressure with mold halves 420, 430. After being variously injected, pressurized and/or otherwise shaped to be disposed around respective circuit components of assembly 410, mold compounds 452, 454 may be cured—e.g., to form package structures such as mold structures 340a, 340b.

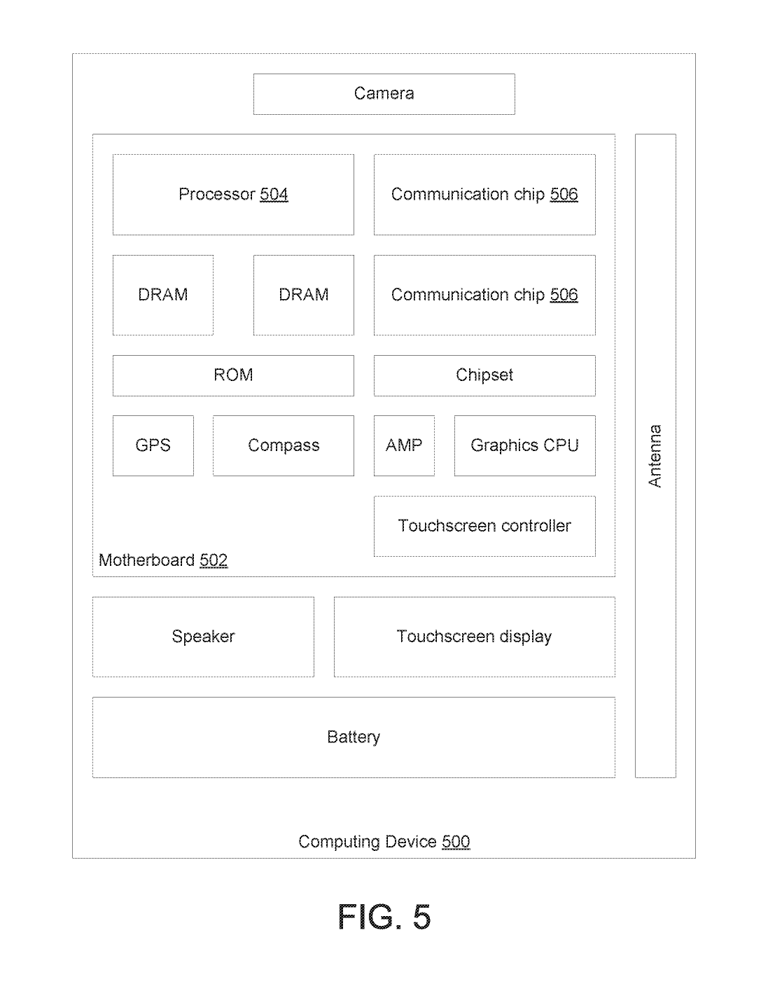

FIG. 5 illustrates a computing device 500 in accordance with one embodiment. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. The term “processor” may refer to any device or portion of a device that processes electronic data from registers and/or memory to transform that electronic data into other electronic data that may be stored in registers and/or memory. The communication chip 506 also includes an integrated circuit die packaged within the communication chip 506.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

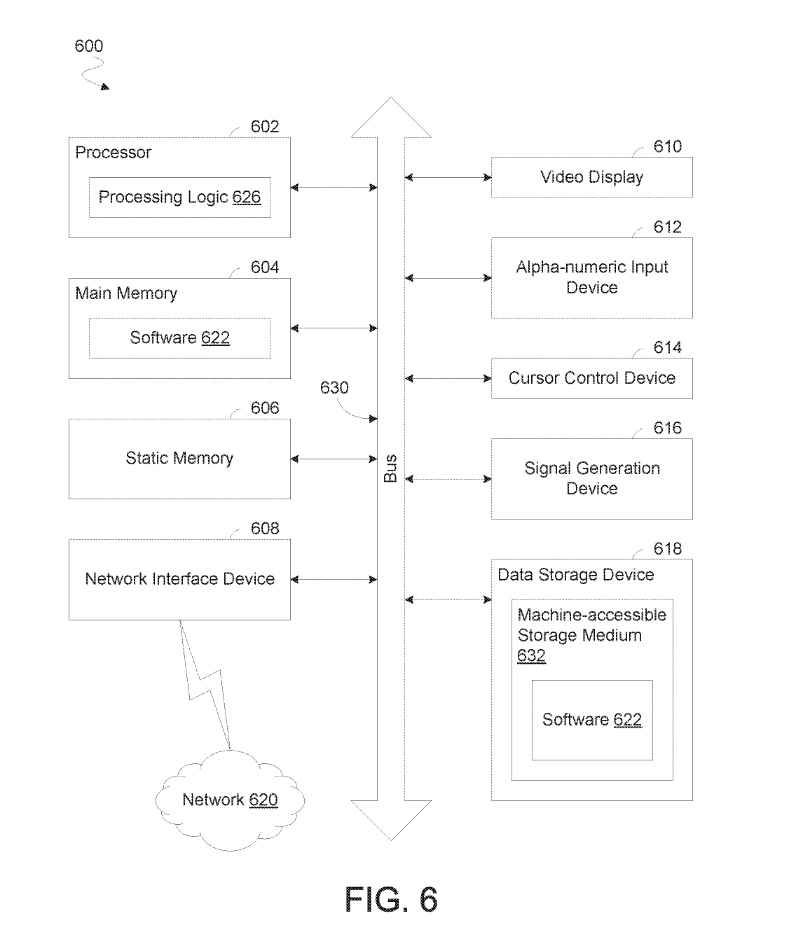

FIG. 6 illustrates a diagrammatic representation of a machine in the exemplary form of a computer system 600 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 600 includes a processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

Processor 602 represents one or more general-purpose processing devices such as a microprocessor, central processing unit, or the like. More particularly, the processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. Processor 602 is configured to execute the processing logic 626 for performing the operations described herein.

The computer system 600 may further include a network interface device 608. The computer system 600 also may include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium (or more specifically a computer-readable storage medium) 632 on which is stored one or more sets of instructions (e.g., software 622) embodying any one or more of the methodologies or functions described herein. The software 622 may also reside, completely or at least partially, within the main memory 604 and/or within the processor 602 during execution thereof by the computer system 600, the main memory 604 and the processor 602 also constituting machine-readable storage media. The software 622 may further be transmitted or received over a network 620 via the network interface device 608.

While the machine-accessible storage medium 632 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

In one implementation, a method comprises coupling first circuit structures to a first release layer, coupling second circuit structures to a second release layer, while the first circuit structures are coupled to the first release layer, while the second circuit structures are coupled to the second release layer, and while the first release layer and the second release layer are on opposite respective sides of a substrate including one or more core layers, disposing a first mold compound portion around the first circuit structures, and disposing a second mold compound portion around the second circuit structures.

In an embodiment, the method further comprises curing the first mold compound portion to form a first package structure, and curing the second mold compound portion to form a second package structure. In another embodiment, the method further comprises after curing the first mold compound portion and curing the second mold compound portion, forming a first packaged device by separating the first package structure and the first circuit components from some or all of the substrate. In another embodiment, the method further comprises forming a second packaged device by separating the second package structure and the second circuit components from some or all of the substrate. In another embodiment, the first package structure includes a flexible package structure. In another embodiment, disposing the first mold compound portion includes injection molding the first mold compound portion. In another embodiment, the first release layer and the second release layer includes one or more peelable films. In another embodiment, the first mold compound portion and the second mold compound comprise different respective mold compounds. In another embodiment, the substrate includes multiple core layers. In another embodiment, coupling the first circuit structures to the first release layer includes coupling the first circuit structures to a first core layer via the first release layer, and wherein coupling the second circuit structures to the second release layer includes coupling the second circuit structures to a second core layer via the second release layer, wherein the method further comprises, after coupling the first circuit structures to the first release layer and after coupling the second circuit structures to the second release layer, forming the substrate, including coupling the first core layer to the second core layer. In another embodiment, the first circuit structures and the second circuit structures each include a respective integrated circuit chip.

In another implementation, a device comprises a substrate including one or more core layers, a first release layer disposed on a first side of the substrate, a second release layer disposed on a second side of the substrate, the second side opposite the first side, first circuit structures coupled to the substrate via the first release layer, second circuit structures coupled to the substrate via the second release layer, a first package structure disposed around the first circuit structures, and a second package structure disposed around the first circuit structures. In an embodiment, the first release layer and the second release layer includes one or more peelable films. In another embodiment, the first mold compound portion and the second mold compound comprise different respective mold compounds. In another embodiment, the substrate includes multiple core layers. In another embodiment, the first circuit structures and the second circuit structures each include a respective integrated circuit chip.

In another implementation, a non-transitory computer-readable storage medium having stored thereon instructions which, when executed by one or more processing units, cause the one or more processing units to perform a method comprising coupling first circuit structures to a first release layer, coupling second circuit structures to a second release layer, while the first circuit structures are coupled to the first release layer, while the second circuit structures are coupled to the second release layer, and while the first release layer and the second release layer are on opposite respective sides of a substrate including one or more core layers, disposing a first mold compound portion around the first circuit structures, and disposing a second mold compound portion around the second circuit structures.

In an embodiment, the method further comprises curing the first mold compound portion to form a first package structure, and curing the second mold compound portion to form a second package structure. In another embodiment, the method further comprises, after curing the first mold compound portion and curing the second mold compound portion, forming a first packaged device by separating the first package structure and the first circuit components from some or all of the substrate. In another embodiment, the method further comprises forming a second packaged device by separating the second package structure and the second circuit components from some or all of the substrate. In another embodiment, the first package structure includes a flexible package structure. In another embodiment, disposing the first mold compound portion includes injection molding the first mold compound portion. In another embodiment, the first release layer and the second release layer includes one or more peelable films. In another embodiment, the first mold compound portion and the second mold compound comprise different respective mold compounds. In another embodiment, the substrate includes multiple core layers. In another embodiment, coupling the first circuit structures to the first release layer includes coupling the first circuit structures to a first core layer via the first release layer, and wherein coupling the second circuit structures to the second release layer includes coupling the second circuit structures to a second core layer via the second release layer, the method further comprises, after coupling the first circuit structures to the first release layer and after coupling the second circuit structures to the second release layer, forming the substrate, including coupling the first core layer to the second core layer. In another embodiment, the first circuit structures and the second circuit structures each include a respective integrated circuit chip.

Techniques and architectures for packaging integrated circuitry are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

1.-25. (canceled)

26. method comprising:
coupling first circuit structures to a first release layer;
coupling second circuit structures to a second release layer;
while the first circuit structures are coupled to the first release layer, while the second circuit structures are coupled to the second release layer, and while the first release layer and the second release layer are on opposite respective sides of a substrate including one or more core layers:
disposing a first mold compound portion around the first circuit structures; and
disposing a second mold compound portion around the second circuit structures.

27. The method of claim 26, further comprising:
curing the first mold compound portion to form a first package structure; and
curing the second mold compound portion to form a second package structure.

28. The method of claim 27, further comprising:
after curing the first mold compound portion and curing the second mold compound portion, forming a first packaged device by separating the first package structure and the first circuit components from some or all of the substrate.

29. The method of claim 28, further comprising forming a second packaged device by separating the second package structure and the second circuit components from some or all of the substrate.

30. The method of claim 27, wherein the first package structure includes a flexible package structure.

31. The method of claim 26, wherein disposing the first mold compound portion includes injection molding the first mold compound portion.

32. The method of claim 26, wherein the first release layer and the second release layer includes one or more peelable films.

33. The method of claim 26, wherein the first mold compound portion and the second mold compound comprise different respective mold compounds.

34. The method of claim 26, wherein the substrate includes multiple core layers.

35. The method of claim 26, wherein coupling the first circuit structures to the first release layer includes coupling the first circuit structures to a first core layer via the first release layer, and wherein coupling the second circuit structures to the second release layer includes coupling the second circuit structures to a second core layer via the second release layer, the method further comprising:
after coupling the first circuit structures to the first release layer and after coupling the second circuit structures to the second release layer, forming the substrate, including coupling the first core layer to the second core layer.

36. The method of claim 26, wherein the first circuit structures and the second circuit structures each include a respective integrated circuit chip.

37. A device comprising:
a substrate including one or more core layers;
a first release layer disposed on a first side of the substrate;
a second release layer disposed on a second side of the substrate, the second side opposite the first side;
first circuit structures coupled to the substrate via the first release layer;
second circuit structures coupled to the substrate via the second release layer;
a first package structure disposed around the first circuit structures; and
a second package structure disposed around the first circuit structures.

38. The device of claim 37, wherein the first release layer and the second release layer includes one or more peelable films.

39. The device of claim 37, wherein the first mold compound portion and the second mold compound comprise different respective mold compounds.

40. The device of claim 37, wherein the substrate includes multiple core layers.

41. The device of claim 37, wherein the first circuit structures and the second circuit structures each include a respective integrated circuit chip.

42. A non-transitory computer-readable storage medium having stored thereon instructions which, when executed by one or more processing units, cause the one or more processing units to perform a method comprising:
coupling first circuit structures to a first release layer;
coupling second circuit structures to a second release layer;
while the first circuit structures are coupled to the first release layer, while the second circuit structures are coupled to the second release layer, and while the first release layer and the second release layer are on opposite respective sides of a substrate including one or more core layers:
disposing a first mold compound portion around the first circuit structures; and
disposing a second mold compound portion around the second circuit structures.

43. The computer-readable storage medium of claim 42, the method further comprising:
curing the first mold compound portion to form a first package structure; and
curing the second mold compound portion to form a second package structure.

44. The computer-readable storage medium of claim 43 the method further comprising:
after curing the first mold compound portion and curing the second mold compound portion, forming a first packaged device by separating the first package structure and the first circuit components from some or all of the substrate.

45. The computer-readable storage medium of claim 44, the method further comprising forming a second packaged device by separating the second package structure and the second circuit components from some or all of the substrate.
